(19) United States
(12) Patent Application Publication
(10) Pub. No.: US 2012/0229161 A1
(43) Pub. Date: Sep. 13, 2012

(54) Method For Detecting Underperforming Solar Wafers In A Solar Panel or Underperforming Solar Panel in a Solar Array

(75) Inventors: Yu-Chih Chen, Danville, CA (US); Hsi Sheng Chen, Fremont, CA (US)

(73) Assignee: E-LIGHTRIC, INC., Monte Sereno, CA (US)

(21) Appl. No.: 13/414,310

(22) Filed: Mar. 7, 2012

Related U.S. Application Data
(60) Provisional application No. 61/451,969, filed on Mar. 11, 2011.
(60) Provisional application No. 61/566,569, filed on Dec. 2, 2011.

(51) Int. Cl. G01R 31/26

(52) U.S. Cl. 324/761.01

(57) ABSTRACT

A method in a solar panel including one or more bypass diodes coupled to one or more sections of solar wafers includes measuring a current flowing through each section of the solar panel; measuring a current flowing through each bypass diode; and assessing the measured current value of the one or more sections of the solar panel and the measured current values of the bypass diodes to determine if the solar panel is malfunctioning. In another embodiment, the method measures a current flowing through the solar panel and through the bypass diodes to determine if the solar panel is malfunctioning. In another embodiment, a method in a solar array determines an underperforming solar panel by measuring the output current and the output voltage of the solar panels in the array.

### CROSS-REFERENCE TO RELATED APPLICATIONS

This application claims the benefit of U.S. Provisional Patent Application Ser. No. 61/451,969, filed on Mar. 11, 2011, and U.S. Provisional Patent Application Ser. No. 61/566,569, filed on Dec. 2, 2011, which applications are incorporated herein by reference in their entireties.

### FIELD OF THE INVENTION

The invention relates to solar panels and, in particular, to a device and a method for monitoring underperforming solar wafers in a solar panel or underperforming solar panels in a solar array.

### DESCRIPTION OF THE RELATED ART

A solar panel, also referred to as a photovoltaic panel, a solar module, or a photovoltaic module, is a packaged interconnected assembly of solar cells (also referred to as “solar wafers” or “photovoltaic cells”). FIG. 1(a) illustrates a conventional solar panel 1 including an assembly of solar cells 2 interconnected in a two-dimensional array. Solar panels use light energy (photons) from the sun to generate electricity through photovoltaic effect (i.e., the photo-electric effect). In a solar panel, the solar cells are connected electrically in series and in parallel to generate the desired output voltage and output current. More specifically, solar cells in a solar panel are connected in series to create an additive voltage and connected in parallel to yield a higher current.

FIG. 1(b) illustrates a single solar cell 2 including two bus bars 3 forming the electrical contacts of the solar cell. Solar cell 2 includes bus bars 3 formed on the front side (sun up) and also the back side (not shown) of the solar cell. Solar cells 2 are connected in series to form a column of the solar panel 1 by connecting the bus bars on the front side of one solar cell to the bus bars on the back side of the next solar cell and so on. Conductive wires or traces connect the bus bars at the ends of the columns of solar cells to form a serial or parallel connection from the columns of solar cells.

Because a single solar panel can only produce a limited amount of power, most photovoltaic installations involves connecting multiple solar panels into an array. A photovoltaic system or a solar system typically includes an array of solar panels, an inverter, batteries and interconnection wiring. Solar panels are interconnected, in series or parallel, or both, to create a solar array providing the desired peak voltage and current.

Once the solar cells are assembled into a panel, there is limited access to identify or monitor the individual solar cells. Should any one cell in a solar panel malfunctions, or any one solar panel in a solar array malfunctions, there will be a claim of warranty replacement or repair by the user. However, solar panel suppliers have only limited ability to monitor the output performance of the solar cells or solar panels throughout their operational life in order to validate the warranty claim. The limited access to the solar panels in an installation and to the solar wafers in a solar panel makes product failure analysis and quality correlation study difficult and economically challenging. Inability to monitor individual solar cell or individual solar panel often leads to excess cost over the life time of the panel, also requires more labor maintenance or repairing or expensive replacement.

### SUMMARY OF THE INVENTION

According to one embodiment of the present invention, a method in a solar panel including one or more bypass diodes coupled to one or more sections of solar wafers in the solar panel includes: measuring a current flowing through each of the one or more sections of the solar panel; measuring a current flowing through each of the one or more bypass diodes; assessing the measured current values of the one or more sections of the solar panel and the measured current value of each of the the bypass diodes; and generating a signal indicating a section of the solar panel is underperforming when the measured current value of the section of the solar panel is below a nominal value and the measured current value of the bypass diode associated with that section of the solar panel is above a minimal value.

According to another aspect of the present invention, a method in a solar panel including one or more bypass diodes coupled to one or more sections of solar wafers in the solar panel includes measuring a current flowing through the solar panel; measuring a current flowing through each of the one or more bypass diodes; assessing the measured current value of the solar panel and the measured current value of the bypass diode associated with each section of the solar panel; generating a signal indicating the solar panel is underperforming when the measured current value of the solar panel is below a nominal value; and generating a signal indicating a section of the solar panel is underperforming when the measured current value of the bypass diode associated with that section of the solar panel is above a minimal value.

According to another aspect of the present invention, a method in a solar array including multiple solar panels where each solar panel includes one or more bypass diodes coupled to one or more sections of solar wafers in the solar panel includes: measuring an output current and an output voltage for each of the plurality of solar panels in the solar array; determining a highest output voltage value from the measured output voltage values of the plurality of solar panels; determining if the measured output voltage value of a solar panel is a fraction of the highest output voltage value; and generating a signal indicating a solar panel is underperforming when the measured output voltage value of the solar panel is a fraction of the highest output voltage value.

The present invention is better understood upon consideration of the detailed description below and the accompanying drawings.

### BRIEF DESCRIPTION OF THE DRAWINGS

FIG. 1(a) illustrates a conventional solar panel including an assembly of solar cells interconnected in a two-dimensional array.

FIG. 1(b) illustrates a single solar cell including two bus bars forming the electrical contacts of the solar cell.

FIG. 2 illustrates a typical solar panel.

FIG. 3, which includes FIGS. 3(a) and 3(b), illustrates an exemplary solar power system where N solar panels are connected in series to form a solar array.

FIG. 4(a) is a schematic diagram illustrating the equivalent circuit of a series of solar panels each with a bypass diode connected thereto.

FIG. 4(b) is a schematic diagram illustrating the equivalent circuit of a solar panel with panel partitions where each partition has a bypass diode connected thereto.

FIG. 5(a) is a diagram of the internal construction of a solar panel junction box including a bypass diode installed between the cathode and anode terminals of the solar panel.

FIG. 5(b) is a diagram of the internal construction of a solar panel junction box including a set of bypass diodes installed between the cathode and anode terminals of each solar panel section.

FIG. 6 is a schematic diagram illustrating the equivalent circuit of a solar panel employing bypass diodes with current sensing elements incorporated therein to implement the underperforming solar wafer detection method according to one embodiment of the present invention.

FIG. 7 illustrates a differential amplifier which can be used to measure the voltage across a current sense element according to one embodiment of the present invention.

FIG. 8 is a schematic diagram illustrating the equivalent circuit of a solar panel employing a single bypass diode with current sensing elements incorporated therein to implement the underperforming solar wafer detection method according to an alternate embodiment of the present invention.

FIGS. 9(a) and 9(b) are schematic diagram illustrating the equivalent circuit of a solar panel employing bypass diodes with current sensing elements incorporated therein to implement the underperforming solar wafer detection method according to alternate embodiments of the present invention.

FIG. 10 is a current-voltage (I-V) data plot of solar panels where the X-axis represents output voltage and the Y-axis represents output current.

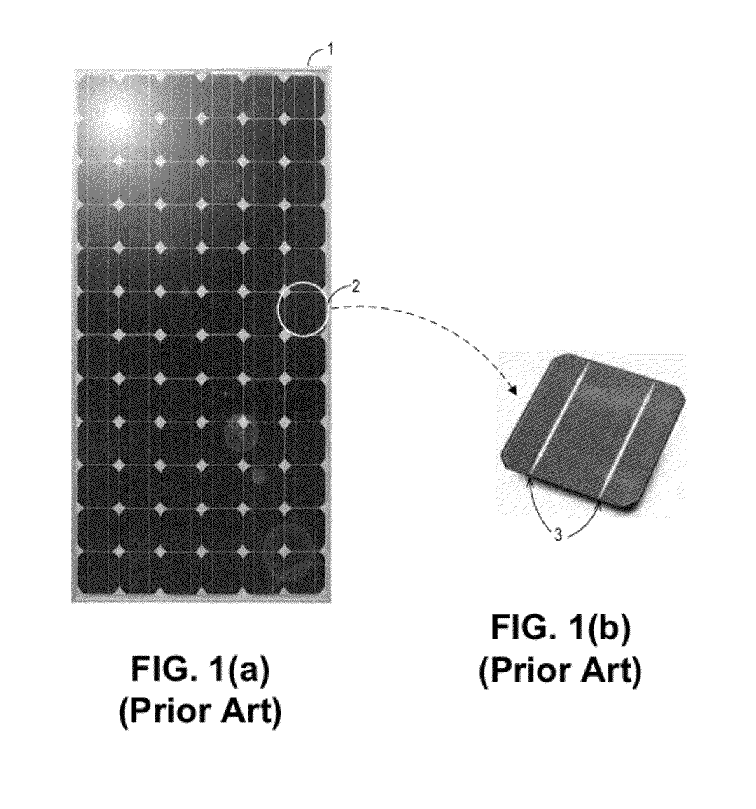

### DETAILED DESCRIPTION OF THE PREFERRED EMBODIMENTS

According to one aspect of the present invention, a method for detecting an underperforming solar wafer in a solar panel or detecting an underperforming solar panel in a solar array monitors the current flow through the solar wafers relative to the current flow through one or more bypass diodes on the solar panel. A solar wafer or a solar panel may be underperforming when it becomes defective or suffers from device failure. A solar wafer or a solar panel may also be underperforming when it experiences temporary performance degradation, such as due to shade. In the present description, an underperforming solar wafer or an underperforming solar panel refers to a solar wafer or a solar panel that is generating less power than the wafer/panel was originally designed for. The method of the present invention enables one or more underperforming solar wafers in a solar panel, or one or more underperforming solar panels in a solar array to be detected and identified.

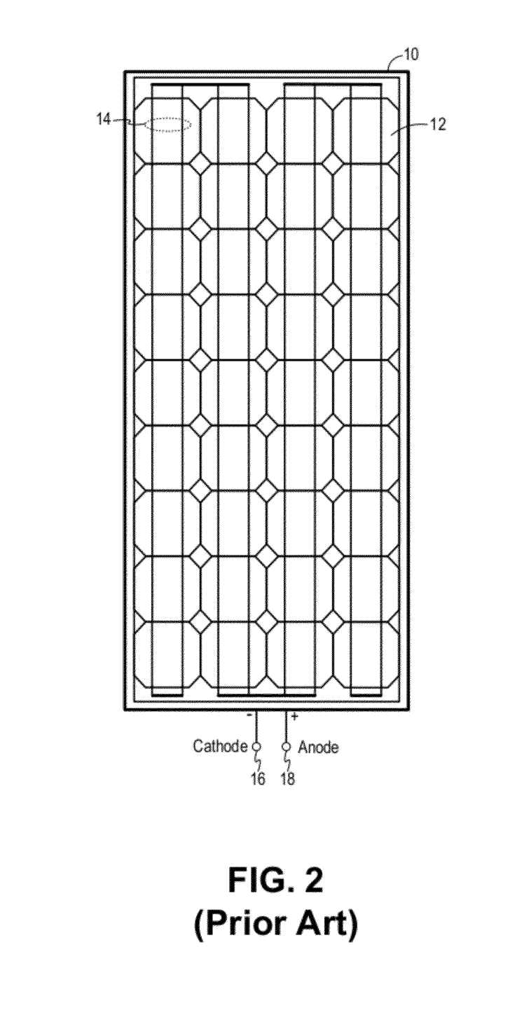

FIG. 2 illustrates a typical solar panel. Referring to FIG. 2, a solar panel 10 includes an assembly of a two-dimensional array of interconnected solar cells 12. In the present illustration, each solar cell 12 includes two conductive traces (bus bars) 14 formed on the front side and two conductive traces (bus bars) formed on the back side (not shown) of the solar cell. In the present illustration, the bus bars 14 are connected at the ends of the solar panel 10 to form a serial connection of solar cells. Other combinations of solar cells, including serial or parallel combinations, are also possible by connecting the bus bars accordingly. Solar panel 10 includes external connectors 18 and 16 for connecting to the most positive node (the Anode) and the most negative node (the Cathode) of the solar panel.

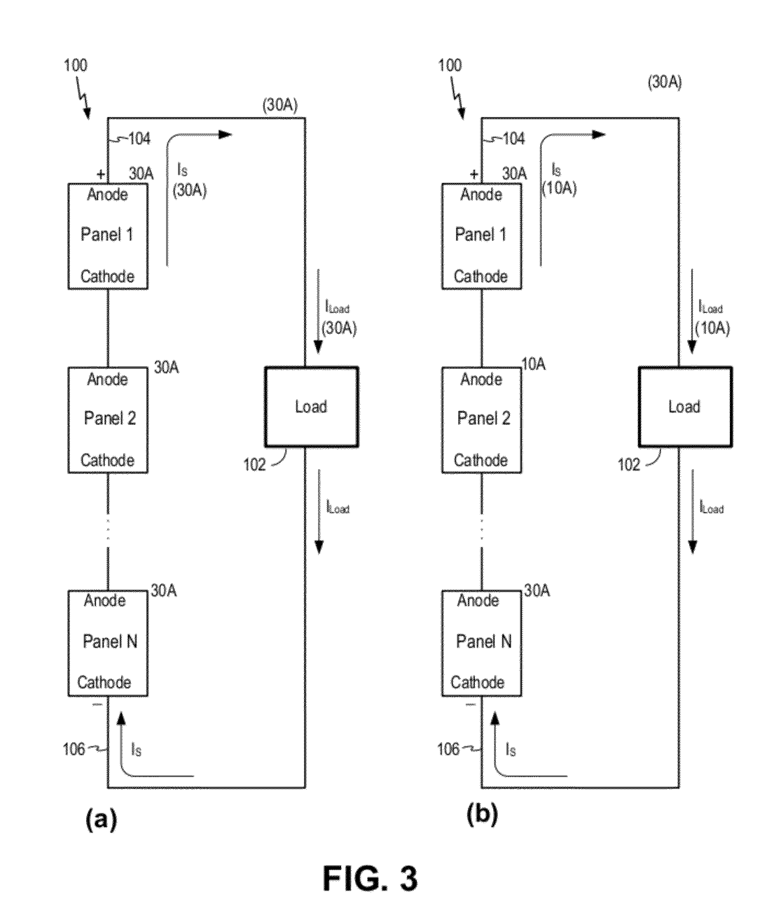

In a solar power system, at least some of the solar panels are connected in series to form a solar array. FIG. 3, which includes FIGS. 3(a) and 3(b), illustrates an exemplary solar power system where N solar panels are connected in series to form a solar array 100. In operation, the solar array 100 delivers power to a load 102. When all the solar panels are functioning, the solar array 100 supplies a given amount of output current I_{S} which is delivered to the load 102 as the load current I_{Load}.

More specifically, the solar array output current I_{S} flows from the anode of the solar power system (the positive terminal 104) to the load and the current then returns to the cathode of the solar power system (the negative terminal 106). In the solar array, the solar panel output current flows from the cathode terminal to the anode terminal of each solar panel. The load may demand a load current I_{Load} that is less than or equal to the maximum current generating capability of the solar wafers.

For a series chain of solar panels to generate a given output current (e.g. 30A) to meet the load current requirement, each panel must be able to generate the desired output current (30A), as shown in FIG. 3(a). However, if one of the panels malfunctions or suffers from temporary performance degradation, the output current of the entire chain of solar panels will be affected. For example, as shown in FIG. 3(b), if Panel 2 of the N solar panels malfunctions or becomes shaded and can only sustain 10A of output current, then the output current of the entire chain of solar panels will become downgraded to the lowest current value, which is 10A in the present example. Thus, the load only receives 10A from the solar power system. Such solar system performance degradation is undesirable as one defective solar panel affects the overall performance of the entire solar array. Moreover, when a solar system operator observes system performance degradation, there is no way to determine which individual solar panel in the array is at fault without laborious disassembly of the solar panel installation and inspection of each individual panel.

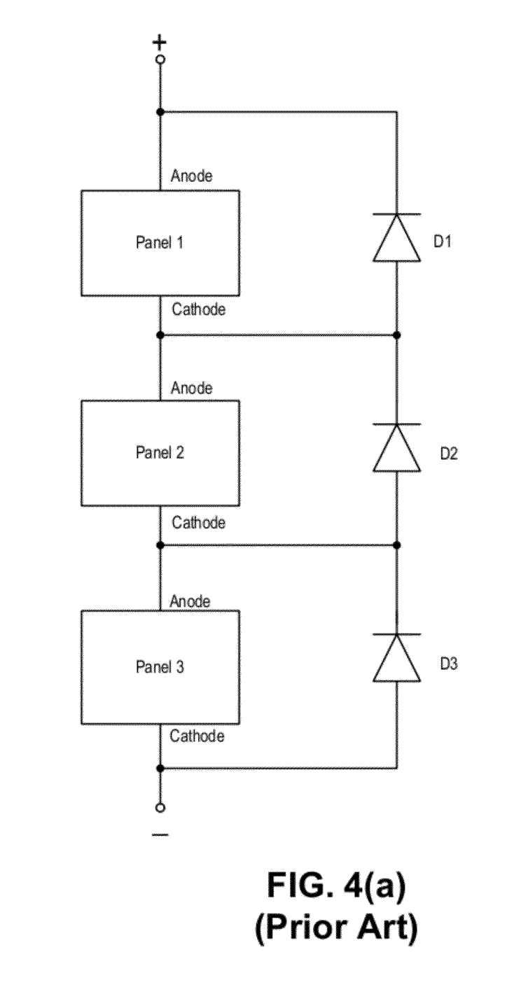

One solution currently used to address the defective solar panel issue is to install a bypass diode between the anode and cathode terminals of the solar panel. FIG. 4(a) is a schematic diagram illustrating the equivalent circuit of a series of solar panels each with a bypass diode connected thereto. The cathode of each bypass diode (D1, D2 or D3) is connected to the anode of the associated solar panel and the anode of each bypass diode is connected to the cathode of the associated solar panel. The bypass diode D1, D2 or D3 is connected in such a way that the bypass diode is reversed biased when the solar panel is functioning. That is, when the solar wafers in the solar panel are capable of supplying the load current demanded by the load, the bypass diode (D1-D3) associated with the solar panel is reversed biased.

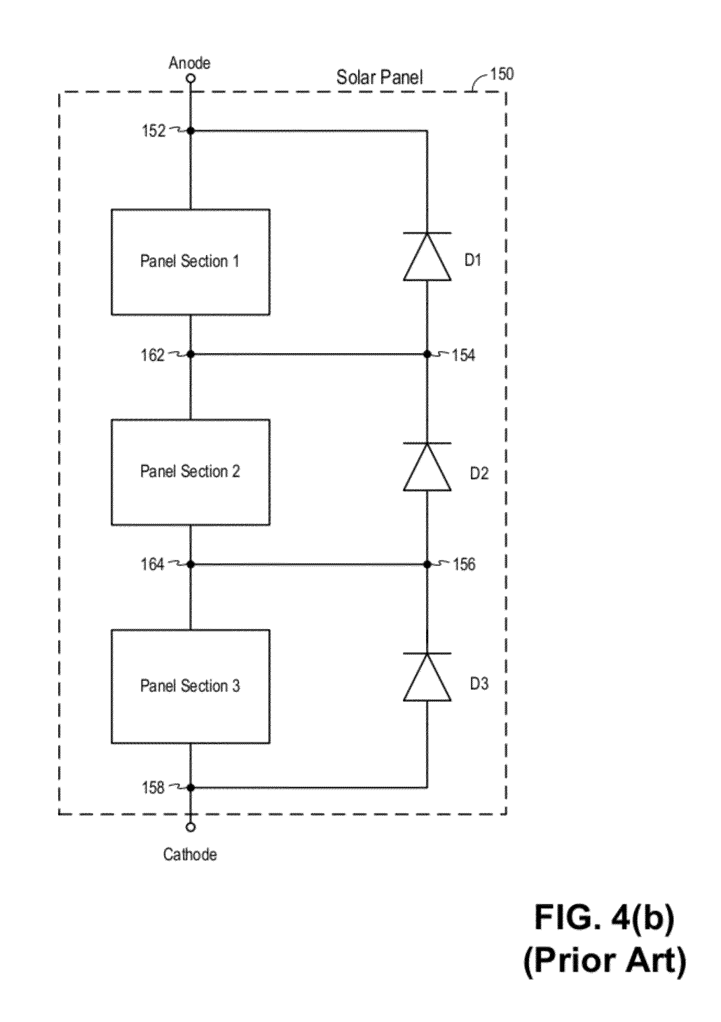

However, when a solar panel malfunctions or suffers from temporary performance degradation, the underperforming solar panel may not be able to meet the load current demand of the load. In that case, all the other solar panels delivers the required load current while the underperforming solar panel will allow only a portion of the load current to flow through the solar panel. The bypass diode becomes forward biased to provide a path for the additional current to pass. Thus, when a solar panel suffers from performance degradation so that it can no longer support the load current demand, the bypass diode will become forward biased and a portion of the load current flows through the underperforming solar panel while remaining current flows through the forward-biased bypass diode. In this manner, the output current of the solar array will bypass the underperforming solar panel so as not to adversely degrade the performance of the entire solar array. The bypass diode is typically installed between the cathode and anode terminals of the solar panel in the junction box of the solar panel, as shown in FIG. 5(a).

When a single bypass diode is used, the entire panel is bypassed even though only one or a few solar wafers in the panel may be defective. In some cases, the solar panel is partitioned into two or more sections and each section is provided with its own bypass diode. FIG. 4(b) is a schematic diagram illustrating the equivalent circuit of a solar panel with panel partitions where each partition has a bypass diode connected thereto. In this example, a solar panel is partitioned into three sections (Panel Section 1, Panel Section 2, Panel Section 3) and each section is connected to a bypass diode (D1, D2 and D3, respectively). When the solar panel is functioning normally, diodes D1, D2 and D3 are reversed biased and the solar wafers in each partition supply the load current demanded by the load.

However, when one or more solar wafers in a section of the solar panel malfunctions or underperforms, that panel section may no longer be able to support the load current demand. In that case, the associated bypass diode becomes forwarded biased to carry the excess load current. That is, the excess load current not supported by the underperforming panel section bypass the underperforming panel section. Accordingly, the solar panel is capable of supporting the load current demand, despite one or more solar wafers in the panel underperforming. The bypass diodes are typically installed between the cathode and anode terminals and panel section contact pads in the junction box of the solar panel, as shown in FIG. 5(b).

The use of bypass diodes allow excess load current to bypass an underperforming solar panel in a solar array or an underperforming section of solar wafers in a solar panel so that the desired output current level of the solar system can be maintained. However, the use of bypass diodes does not provide an indication of which solar panel or which section of the solar panel is malfunctioning. Determining the underperforming solar panel still requires the laborious process of disassembling the solar panel installation.

According to embodiments of the present invention, a method for detecting an underperforming solar wafer in a solar panel or an underperforming solar panel in a solar array measures the current flowing through the solar wafers and the current flowing through the associated bypass diode. The solar wafer current and the bypass diode current are evaluated to generate an indication of malfunctioning conditions.

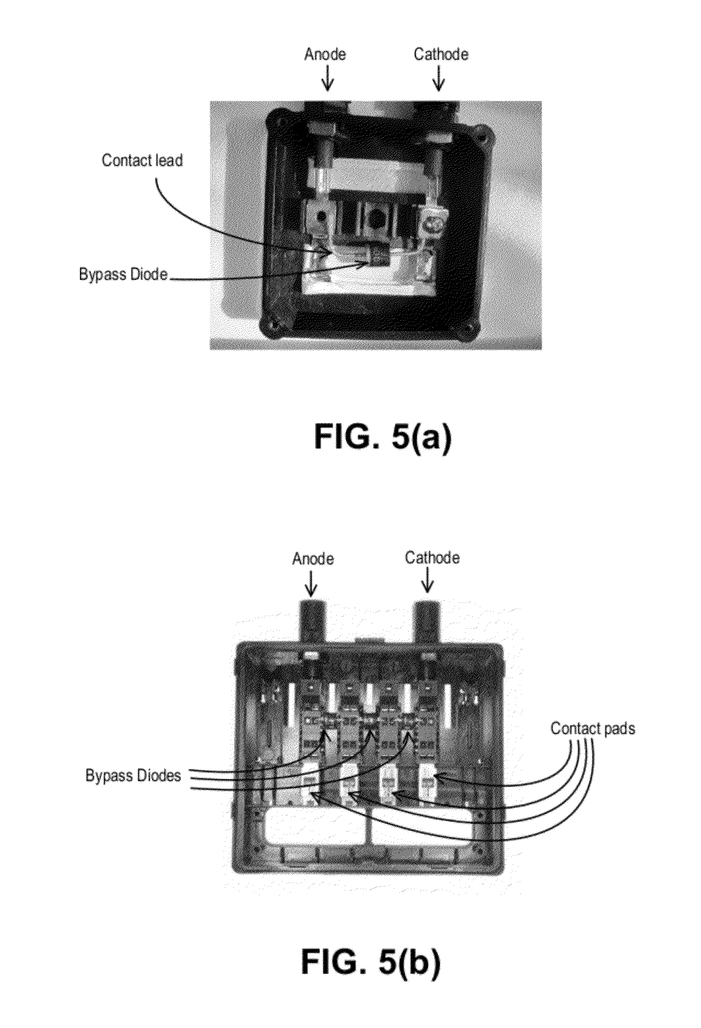

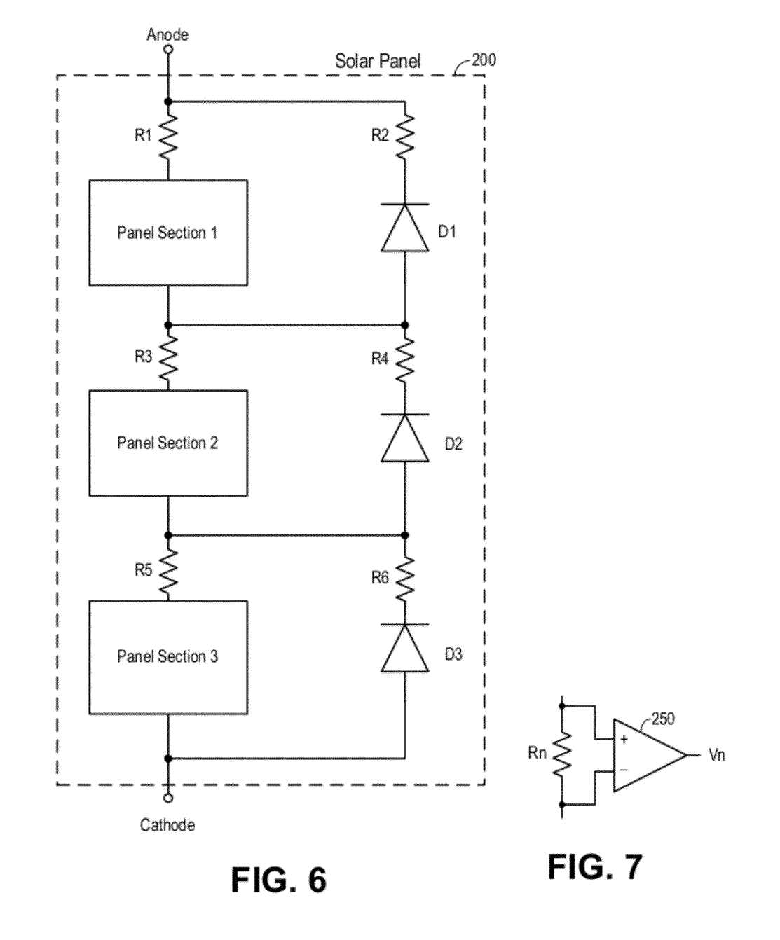

FIG. 6 is a schematic diagram illustrating the equivalent circuit of a solar panel employing bypass diodes with current sensing elements incorporated therein to implement the underperforming solar wafer detection method according to one embodiment of the present invention. Referring to FIG. 6, in a solar panel 200 provided with panel partitions (Panel Sections 1 to 3) and bypass diodes (D1 to D3) for each panel partition, a current sensing element (R1, R3 or R5) is added to each solar panel section to measure the current flow through each panel section and a current sensing element (R2, R4, or R6) is also added to each bypass diode to measure the current flow through the bypass diode. In the present embodiment, the current sensing elements are resistors. More specifically, a resistor R1 is connected in series with Panel Section 1, a resistor R3 is connected in series with Panel Section 2, and a resistor R5 is connected in series with Panel Section 3. Moreover, a resistor R2 is connected in series with the cathode terminal of bypass diode D1, a resistor R4 is connected in series with the cathode terminal of bypass diode D2, and a resistor R6 is connected in series with the cathode terminal of bypass diode D3. As thus configured, current flowing through a panel section will cause a voltage drop across the respective resistor R1, R3 or R5. On the other hand, current flowing through the bypass diodes, if any, will cause a voltage drop across respective resistor R2, R4 or R6. In some embodiment, the voltage drops across each of resistors R1 to R6 are measured using a differential amplifier 250, as shown in FIG. 7.

In the present embodiment, a resistor is used to measure the current flowing from each solar panel section and each bypass diode. The use of a resistor as a current sensing element is illustrative only. In other embodiments, other current sensing elements can be used to measure the current flow in the solar panel section or the bypass diode. The implementation of the method of the present invention is not limited to the use of resistors only as the current sensing elements.

In operation, the underperforming solar wafer detection method of the present invention measures the voltage drops across the panel resistors (R1, R3 and R5) and the voltage drops across the bypass diode resistors (R2, R4 and R6). In one embodiment, the voltage values are measured periodically and stored in a memory. The measured voltages are indicative of the current flowing through the solar panel sections and the bypass diodes, respectively, and are used as an indicator of a defective or underperforming solar panel section.

More specifically, in some embodiments, the method of the present invention is operative to sample the voltage drops across the resistors R1 to R6 at predetermined time intervals and store the sampled voltage values, such as in a memory. The measured voltage values are indicative of the current flows at each current sensing element (resistors R1 to R6). The measured voltage values are evaluated d to determine if any solar panel section is drawing less than the desired output current and therefore may be malfunctioning or underperforming. In some embodiments, the measured voltage values are used to calculate the currents flowing through each of the resistors R1 to R6. The derived current values are then compared to determine if any solar panel section is drawing less than the desired output current.

In one embodiment, the method compares the panel resistor voltage, such as the voltage across resistor R1, with the associated bypass diode resistor voltage, such as the voltage across resistor R2. Similarly, the voltage across resistor R3 is compared with the voltage across resistor R4 and the voltage across resistor R5 is compared with the voltage across resistor R6. In some embodiments, the method compares derived current values indicative of the current flowing through the panel resistors R1 to R6 to determine if any solar panel section is underperforming.

When a solar panel section is functioning normally, the solar panel section will supply the desired output current, causing a given voltage value to be developed across the associated panel resistor (e.g. R1). Meanwhile, the associated bypass diode (e.g. D1) is reversed biased and no current flows through the bypass diode resistor (e.g. R2). The voltage drop across the bypass diode resistor would be zero or very low. However, when a solar panel section is underperforming, the output current level drops so that the voltage across the associated panel resistor decrease below the nominal voltage value. Meanwhile, the associated bypass diode becomes forward biased to divert the excessive load current not being able to be handled by the underperforming solar panel section. A portion of the desired output current flows through the bypass diode (e.g. D1) and a given voltage value will be developed across the associated bypass diode resistor (e.g. R2).

By evaluating the voltages or currents measured at the panel resistor and the bypass diode resistor (e.g. R1 and R2), the method of the present invention determines if the solar panel output current is flowing through the solar panel section or if a portion is going through the bypass diode. Accordingly, the method determines if a particular solar panel section is malfunctioning or is underperforming. For instance, a drop in the panel resistor voltage below the nominal voltage value with an increase in the bypass diode resistor voltage above a minimal voltage value is an indication of a failure or malfunction in the solar panel section.

Furthermore, by evaluating each pair of panel resistor and bypass diode resistor voltage values, that is, voltages for resistors R1 and R2, voltages for resistors R3 and R4, and voltages for R5 and R6, the method of the present invention determines if the entire solar panel is underperforming or if only certain solar wafers within certain partition are underperforming.

In some embodiments, the current sensing elements (e.g. resistors) and associated voltage measurement elements (e.g. differential amplifiers) are formed in the junction box of the solar panel. The memory and control circuits may also be accommodated in the junction box of the solar panel.

In embodiments of the present invention, the current measurements from the panel section resistors R1, R3 and R5 are used as an indication of the general health of the solar panel. By accessing the current flowing through the panel section resistors R1, R3 and R5, it is possible to determine if the solar panel is shaded and thus producing less than ideal output current or if the panel is damaged and malfunctioning all together. In actual practice, a solar panel generates some amount of output current between sunrise and sunset, even when the panel may be shaded. However, when the solar panel is damaged or malfunctioning or is entirely blocked from any daylight, the panel will generate no output current at all. Thus, current measurements through the panel section resistor R1, R3 and R5 can be used to indicate the state of health of the solar panel. If there is some amount of current flowing through the panel section and certain amount is bypassed, the solar panel is likely still functioniong and it is only shaded. The amount of current flow can be used to determine how much the panel section is degraded. But if there is no current flowing through the panel section at all, then the solar panel is likely damaged.

In one embodiment of the present invention, the underperforming solar wafer detection method generates an alarm signal when a failure condition is detected. In other embodiments, the underperforming solar wafer detection method further generates performance data including the current measurements of the solar panel sections and the bypass diodes. In some embodiments, the alarm signal and the performance data are stored in a memory. The stored data may be transmitted out of the solar panel via a wired or a wireless communication interface. A host controller may receive and analyze the performance data for overall solar system control. In one embodiment, the alarm signal and the performance data are stored in a memory associated with a wireless communication element, such as an RFID tag. The wireless element includes at least a wireless transceiver and the memory. The alarm signal and the performance data, together with the identification data of the solar panel, can be read out remotely by a wireless reader placed within the communication range of the wireless communication element. In this manner, a solar system operator may determine rapidly which solar panel in a solar panel array installation may be malfunctioning by using a remote reader and bringing the remote reader within the communication range of the wireless communication element. Furthermore, once the defective or underperforming panel is identified, the performance data may also inform the solar system operator which solar panel section in the solar panel is malfunctioning.

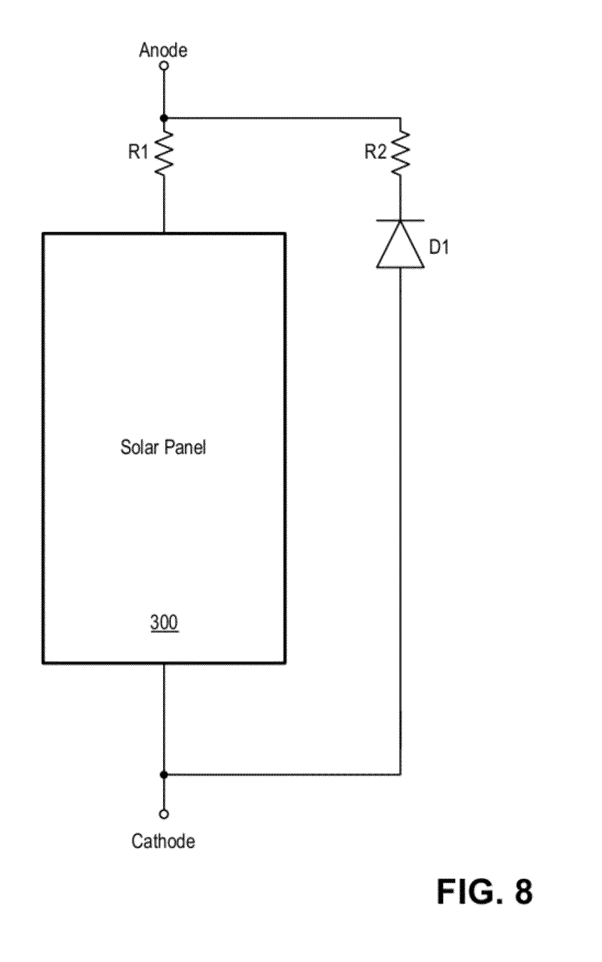

In an alternate embodiment of the present invention, the underperforming solar wafer detection method of the present invention is applied to a solar panel without any partition and using only a single bypass diode for the entire panel. FIG. 8 is a schematic diagram illustrating the equivalent circuit of a solar panel employing a single bypass diode with current sensing elements incorporated therein to implement the underperforming solar wafer detection method according to an alternate embodiment of the present invention. Referring to FIG. 8, a solar panel 300 includes a current sensing element (R1) connect in series with the solar panel and another current sensing element (R2) connected in series with the bypass diode (D1). The method of the present invention measures the voltage across the panel resistor R1 and the voltage across the bypass diode resistor R2 to determine if the solar panel has malfunctioned or is underperforming based on the measured voltage or a derived current value. For instance, a drop in the panel resistor voltage/current with an increase in the bypass diode resistor voltage/current is an indication of performance degradation in the solar panel. The method operates in the same manner as described above and may generate an alarm signal and failure data to indicate the failure condition. The method may also store the alarm signal and transmit the alarm signal via wired or wireless communication, in the same manner as described above. Furthermore, the current measurement from the panel resistor R1 can be used to indicate the health of the solar panel, as described above.

In the above-described embodiments, the solar panel is described as being partitioned into two or more sections, each section containing multiple solar wafers and each section associated with a bypass diode. In other embodiments, the solar panel may be provided with a bypass diode for each solar wafer. In that case, the underperforming solar wafer detection method of the present invention is applied in the same manner to measure the current flow through each solar wafer and through each bypass diode. Evaluating the voltage drops across the current sensing elements at the solar wafer and at the bypass diode allows the method of the present invention to determine if a particular solar wafer is defective or is underperforming. An alarm signal and failure data may be generated accordingly in the same manner as described above.

In the present description, the term “a panel section” or “a panel partition” as used herein can include one or more solar wafers of the solar panel and may include the solar wafers of the entire solar panel. Thus, a panel section or partition can include one or some of the solar wafers in the solar panel or a panel section can refer to all of the solar wafers in the solar panel. Accordingly, in the present description, a solar panel including a single bypass diode for the entire panel is also described as a solar panel having one panel partition or panel section. The underperforming solar wafer detection method of the present invention can be applied to a solar panel with one or more panel sections, each section containing one or more, or all, of the solar wafers of the solar panel.

### Alternate Embodiments

In the above-described embodiments, the underperforming solar wafer detection method utilizes current sensing elements (e.g. resistors R1, R3 and R5) to measure the current flowing through each solar panel section. In practice, a solar panel commercially available today often does not provide external access to the internal panel section electrical nodes. That is, referring back to FIG. 4(b), in a currently commercially available solar panel 150, the electrical nodes of the panel that are available for external access in the junction box include the anode terminal 152, the cathode terminal 158 and the nodes 154, 156 between the bypass diodes. More specifically, node 154 between the anode of diode D1 and the cathode of D2 and node 156 between the anode of D2 and the cathode of D3 are accessible through the junction box.

In particular, the most negative terminal of Panel Section 1 is electrically connected to the most positive terminal of Panel Section 2 so that node 162 is only available to the bypass diode connection (node 154) but the internal nodes of Panel Sections 1 and 2 are not otherwise accessible in solar panel commercially available today. This is true also for node 164 electrically connecting the most negative terminal of Panel Section 2 to the most positive terminal of Panel Section 3. That is, the panel section terminals connecting to nodes 162 and 164 are encapsulated inside the solar panel construction and not accessible at the junction box. Thus, incorporating current sensing elements to the solar panels commercially available today may involve redesigning of the solar panel construction.

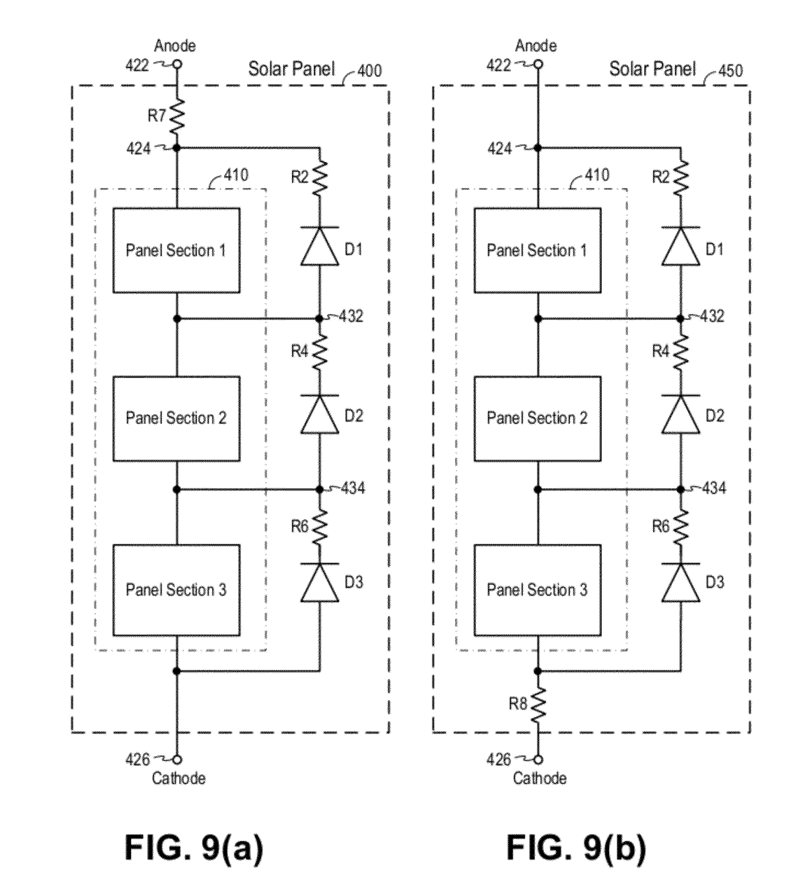

In embodiments of the present invention, the underperforming solar wafer detection method is implemented in a currently commercially available solar panel without requiring design modification to the solar panel. FIGS. 9(a) and 9(b) are schematic diagram illustrating the equivalent circuit of a solar panel employing bypass diodes with current sensing elements incorporated therein to implement the underperforming solar wafer detection method according to alternate embodiments of the present invention.

Referring first to FIG. 9(a), a solar panel 400 includes panel partitions (Panel Sections 1 to 3) and bypass diodes (D1 to D3) for each panel partition. The panel sections and connections of the panel sections are formed within the solar panel construction, denoted by dot-dash box 410 and are not accessible at the junction box of the solar panel. Electrical nodes outside of the dot-dash box 410 are available in the junction box of the solar panel. The bypass diodes D1 to D3 are housed in the junction box and electrically connected to the respective nodes of the solar panel. In the solar panel 400, a current sensing element (R2, R4, or R6) is coupled to each bypass diode to measure the current flow through the bypass diode. Furthermore, a current sensing element (R7) is coupled to the anode terminal to measure the current flow through the solar panel. In the present embodiment, the current sensing elements are resistors.

More specifically, resistor R7 is electrically connected to the anode 422 of the solar panel and a node 424 being the most positive node of Panel Section 1. Resistor R2 is electrically connected to node 424 and the cathode of the bypass diode D1. Resistor R4 is electrically connected to node 432 and the cathode of bypass diode D2. Resistor R6 is electrically connected to node 434 and the cathode of bypass diode D3. The node 432 is the anode of bypass diode D1 and the node between Panel Section 1 and Panel Section 2. The node 434 is the anode of bypass diode D2 and the node between Panel Section 2 and Panel Section 3.

As thus constructed, the method of the present invention measures the current flowing through the solar panel through current sensing element R7 and the current flowing through the bypass diodes through current sensing elements R2, R4 and R6. For instance, the method measures the voltage across resistors R2, R4, R6 and R7 and derives the current values from the measured voltage values.

When there is no malfunctioning solar wafers or solar panel sections, the current flowing through resistor R7 should equal the sum of the current flowing through each panel section and the bypass diode. Thus:

I_{R7}=I_{panel section 1}+I_{R2}=I_{panel section 2}+I_{R4}=I_{panel section 3}+I_{R6}.

The method of the present invention evaluates the current flowing through resistor R7 (I_{R7}) to determine the operational state of the solar panel. The current flowing through resistor R7 is an indication of the general health of the solar panel. If the current flowing through resistor R7 is low, this could be an indication that the solar panel is shaded. However, if there is no current flowing through resistor R7, this could an indication that the entire panel is malfunctioning or damaged. The method of the present invention further evaluates the current flowing through the bypass diodes. When the current flowing through a bypass diode (I_{R2}, I_{R4}, or I_{R6}) increases, the increase in the bypass diode current, together with a normal solar panel current reading (I_{R7}), may indicate a malfunctioning solar wafer(s) in the solar panel section. In this manner, a malfunctioning or underperforming solar panel section can be identified.

FIG. 9(b) illustrates an alternate embodiment of the method of the present invention where a current sensing element (R8) is electrically connected to the cathode terminal of the solar panel to measure the current flowing through the solar panel. The operation of the underperforming solar wafer detection method is the same as the embodiment of FIG. 9(a) and will not be further described in detail. In particular, the current flowing through resistor R8 should equal the sum of the current flowing through each panel section and the bypass diode, as follows:

I_{R8}=I_{panel section 1}+I_{R2}=I_{panel section 2}+I_{R4}=I_{panel section 3}+I_{R6}.

Thus, measurements of the currents flowing through the solar panel (I_{R8}) and through the bypass diodes (I_{R2}, I_{R4}, or I_{R6}) can be used to determine if a particular panel section is malfunctioning or if the entire solar panel is underperforming or is damaged.

### Detection Method using Output Current-Output Voltage

As described above, a solar panel is equipped with bypass diodes for sections of solar wafers to allow excess load current to bypass an underperforming section of solar wafers so that the desired output current level of the solar system can be maintained.

In embodiments of the present invention, a method for detecting an underperforming solar panel in a solar array measures the output voltage and the output current of the solar panel. The measured output voltage and output current are evaluated to determine if one or more sections of solar wafers have been bypassed, indicating one or more sections of underperforming solar wafers. In one embodiment, the underperforming solar wafer detection method is applied to solar panels in a solar array, each of the solar panels being divided into N sections with each section being coupled to a bypass diode. The method measures the output voltage and output current at each and every solar panel of the solar array. The measured solar panel output current and output voltage values for the solar array are evaluated against each other and also compared against a threshold value. In some embodiments, the measurements are performed at predetermined intervals.

More specifically, the method evaluates a given set of measured output current values and the measured output voltage values for the solar panels. The measured output current values and output voltage values may be sorted. In some embodiments, the output current and output voltage values are filtered to eliminate noise in the measured data. The method determines the highest output voltage value from the measured data. The highest output voltage value can be the absolute highest output voltage value of all the measured data or it can be an average value of a given number of voltage values representing the higher output voltage values of all the measured data, such as the top 90% of the output voltage values.

The method determines if a measured output voltage value for a particular solar panel is a fraction of the highest output voltage value. When the measured output voltage for a particular solar panel is a fraction of the highest output voltage value, it is an indication that the solar panel associated with that measured output voltage has one or more sections being bypassed by the bypass diode, which is an indication of an underperforming solar panel.

Furthermore, if a measured output voltage value for a particular solar panel is M/N of the highest output voltage value, where M is an integer less than N, then the solar panel associated with that measured output voltage has (N-M) sections being bypassed, indicating an underperforming solar panel with N-M sections not producing energy at an optimal level.

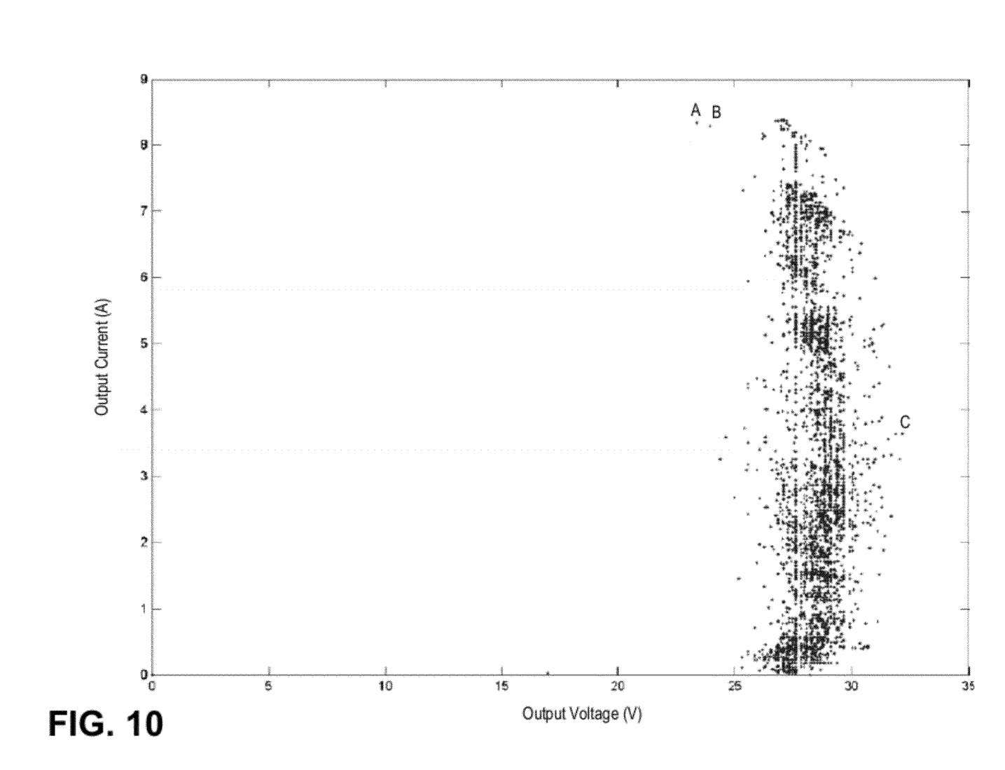

FIG. 10 is a current-voltage (I-V) data plot of solar panels where the X-axis represents output voltage and the Y-axis represents output current. As shown in FIG. 10, the highest output voltage can be represented by a data point C having an output voltage of about 34V. Data points A and B, at about 22V, are about ⅔ of the highest output voltage. Assuming the solar panel has three sections with three bypass diodes, then the underperforming solar wafer detection method operates to determine that data point A and B are operating only at ⅔ of the highest output voltage and thus one section of the associated solar panel being bypassed for underperformance.

The above detailed descriptions are provided to illustrate specific embodiments of the present invention and are not intended to be limiting. Numerous modifications and variations within the scope of the present invention are possible. The present invention is defined by the appended claims.

We claim:

1. A method in a solar panel including one or more bypass diodes coupled to one or more sections of solar wafers in the solar panel, the method comprising:
measuring a current flowing through each of the one or more sections of the solar panel;
measuring a current flowing through each of the one or more bypass diodes;
assessing the measured current value of the one or more sections of the solar panel and the measured current value of each of the bypass diodes; and
generating a signal indicating a section of the solar panel is underperforming when the measured current value of the section of the solar panel is below a nominal value and the measured current value of the bypass diode associated with that section of the solar panel is above a minimal value.

2. The method of claim 1, wherein the nominal value comprises the output current of the solar panel when the solar panel is functioning normally.

3. The method of claim 1, wherein the minimum value comprising zero or a low value.

4. The method of claim 1, wherein measuring a current flowing through each of the one or more sections of the solar panel comprises measuring a voltage drop across a current sensing element coupled in series with each of the one or more sections of the solar panel, and wherein measuring a current flowing through each of the one or more bypass diodes comprises measuring a voltage drop across a current sensing element coupled in series with each of the one or more bypass diodes.

5. The method of claim 4, wherein the current sensing elements associated with the one or more sections of the solar panel and the one or more bypass diodes comprise resistors.

6. The method of claim 1, further comprising:
generating failure data indicating the section of the solar panel that is underperforming;
storing the signal and the failure data in a memory circuit associated with the solar panel; and
transmitting the stored information through a communication interface.

7. The method of claim 6, wherein the communication interface comprises a wired or wireless communication interface.

8. A method in a solar panel including one or more bypass diodes coupled to one or more sections of solar wafers in the solar panel, the method comprising:
measuring a current flowing through the solar panel;
measuring a current flowing through each of the one or more bypass diodes;
assessing the measured current value of the solar panel and the measured current value of the bypass diode associated with each section of the solar panel;
generating a signal indicating the solar panel is underperforming when the measured current value of the solar panel is below a nominal value; and
generating a signal indicating a section of the solar panel is underperforming when the measured current value of the bypass diode associated with that section of the solar panel is above a minimal value.

9. The method of claim 8, wherein the nominal value comprises the output current of the solar panel when the solar panel is functioning normally.

10. The method of claim 8, wherein the minimum value comprising zero or a low value.

11. The method of claim 8, wherein measuring a current flowing through the solar panel comprises measuring a voltage drop across a current sensing element coupled in series with an anode or a cathode terminal of the solar panel, and wherein measuring a current flowing through each of the one or more bypass diodes comprises measuring a voltage drop across a current sensing element coupled in series with each of the one or more bypass diodes.

12. The method of claim 11, wherein the current sensing elements associated with the solar panel and the one or more bypass diodes comprise resistors.

13. The method of claim 8, further comprising:
generating failure data indicating the section of the solar panel that is underperforming;
storing the signal and the failure data in a memory circuit associated with the solar panel; and
transmitting the stored information through a communication interface.

14. The method of claim 13, wherein the communication interface comprises a wired or wireless communication interface.

15. A method in a solar array comprising a plurality of solar panels, each solar panel including one or more bypass diodes coupled to one or more sections of solar wafers in the solar panel, the method comprising:
measuring an output current and an output voltage for each of the plurality of solar panels in the solar array;
determining a highest output voltage value from the measured output voltage values of the plurality of solar panels;
determining if the measured output voltage value of a solar panel is a fraction of the highest output voltage value; and
generating a signal indicating a solar panel is underperforming when the measured output voltage value of the solar panel is a fraction of the highest output voltage value.

16. The method of claim 15, wherein determining a highest output voltage value from the measured output voltage values of the plurality of solar panels comprises determining the highest output voltage by averaging a given number of higher measured output voltage values of the solar panels.

17. The method of claim 16, wherein determining the highest output voltage by averaging a given number of higher measured output voltage values of the solar panels comprises determining the highest output voltage by averaging the top 90% of higher measured output voltage values of the solar panels

18. The method of claim 15, wherein each solar panel comprises N sections of solar wafers and the method further comprises:
determining if the measured output voltage of a solar panel is M/N of the highest output voltage value, where M is an integer less than N; and
generating a signal indicating N-M sections of the solar panel has been bypassed.
